(19) United States
(12) Patent Application Publication
(10) Pub. No.: US 2021/0391848 A1
(43) Pub. Date: Dec. 16, 2021

(54) Surface Acoustic Wave Filter

(71) Applicant: Shoulder Electronics Co., Ltd., Wuxi (CN)

(72) Inventors: Weibiao WANG, Wuxi (CN); Hongqing MAO, Wuxi (CN); Zengtian LU, Wuxi (CN); Zhuang LI, Wuxi (CN)

(21) Appl. No.: 17/283,521

(22) PCT Filed: Apr. 17, 2018
(86) PCT No.: PCT/CN2018/083261

§ 371 Date: Apr. 7, 2021

(30) Foreign Application Priority Data
Mar. 16, 2018 (CN) 201810219984.0

(51) Int. Cl. H03H 9/64; H03H 9/205; H03H 9/02

(52) U.S. Cl. CPC H03H 9/64; H03H 9/058; H03H 9/02559; H03H 9/205

(57) ABSTRACT

This invention discloses a acoustic surface wave filter in the field of acoustic surface wave filters. The acoustic surface wave filter consists of two different piezoelectric substrates, a series resonator group is made on one piezoelectric substrate, and a parallel resonators group is made on the other; The series and parallel resonator groups on the piezoelectric substrates form a trapezoidal structure; the series resonator group is connected with the parallel resonator group; in which the series resonator group is composed of several series resonators and electrodes, and the parallel resonator group is composed of several parallel resonators and electrodes; as a result, the problems that the present acoustic surface wave filters are difficult to satisfy different relative bandwidths and better rectangle coefficient simultaneously are solved; and the effects of increasing the relative bandwidth of the acoustic surface wave filter, reducing the insertion loss and optimizing the rectangle coefficient are achieved.

### FIELD OF THE INVENTION

This invention relates to the field of acoustic surface wave filters, and in particular it relates to an acoustic surface wave filter.

### BACKGROUND OF THE INVENTION

In the modern broadband communication system, the development of filter technology is closely related to the development of communication technology. Based on the rapid development of the fields including satellite communication, electronic station and personal mobile communication, etc., the wireless communication technology continuously develops toward high speed, large capacity and multi-frequency bands, etc., and the acoustic surface wave filters with the features of different bandwidths, especially extra large bandwidth, low loss, small volume and good rectangle coefficient are increasingly demanded, too.

Due to the limitation of material coupling coefficient, realization of the acoustic surface wave filters with different relative bandwidths and good rectangle coefficient is difficult.

### SUMMARY OF THE INVENTION

### Technical problems

Due to the limitation of material coupling coefficient, it is difficult to realize different relative bandwidths and better rectangle coefficient in the present acoustic surface wave filters.

### Technical solutions

An acoustic surface wave filter is provided, which consists of two different piezoelectric substrates, a series resonator group is made on one piezoelectric substrate, and a parallel resonator group is made on the other;

The series and parallel resonator groups on the piezoelectric substrates form a trapezoidal structure;

The series resonator group is connected with the parallel resonator group;

In which, the series resonator group is composed of several series resonators and electrodes, and the parallel resonator group consists of several parallel resonators and electrodes;

Two piezoelectric substrates are made of different types of materials (optional);

One piezoelectric substrate is made of lithium niobate, and the other is made of lithium tantalate or quartz;

Two piezoelectric substrates are lithium niobate substrates in different tangential directions (optional);

The tangential direction of lithium niobate substrates is any value between 0° and 64° of rotation Y.

When the piezoelectric substrates are made of lithium niobate, the electrodes can be made of any of copper, tungsten and gold (optional);

When the piezoelectric substrates are made of lithium tantalate, the electrodes are made of aluminum;

The thicknesses of electrodes in the series resonator group and parallel resonator group are the same or different (optional);

The series resonator group is connected with the parallel resonator group through interconnected welding wire (optional);

The series resonator group is connected with the parallel resonator group through support plates (optional).

### Beneficial Effects

The acoustic surface wave filter disclosed in this application consists of two different piezoelectric substrates, a series resonator group is made on one piezoelectric substrate, and a parallel resonators group is made on the other. Two piezoelectric substrates are made of different types of materials or of the same materials and in different tangential directions, therefore, two piezoelectric substrates exhibit different temperature coefficient and coupling coefficient. The acoustic surface wave filter made of two piezoelectric substrates at different temperature coefficient and coupling coefficient can satisfy the rectangle coefficient with different demands, increase the relative bandwidth and reduce the insertion loss of the acoustic surface wave filter.

### BRIEF DESCRIPTION OF THE DRAWINGS

FIG. 1 is the structural schematic diagram of an acoustic surface wave filter shown according to an example of the implementation cases;

FIG. 2 is the sectional schematic diagram of an acoustic surface wave filter shown according to an example of the implementation cases;

FIG. 3 is the structural schematic diagram of a support plate shown according to another example of the implementation cases;

FIG. 4 is the diagram of simulation result of an acoustic surface wave filter shown according to another example of the implementation cases.

### DETAILED DESCRIPTION OF THE INVENTION WITH EMBODIMENTS

An acoustic surface wave filter provided in one implementation case of this invention, and in which two different piezoelectric substrates are included.

Two piezoelectric substrates are made of different types of materials, or, made of the same materials and in different tangential directions.

Two piezoelectric substrates made of different types of materials or in different tangential directions exhibit different temperature coefficient and coupling coefficient, and the acoustic surface wave filter made of two piezoelectric substrates at different temperature coefficient and coupling coefficient can satisfy the rectangle coefficient with different demands.

A series resonator group is made on one piezoelectric substrate.

The series resonator group is composed of several series resonators and electrodes.

The number of resonators included in the series resonator group is determined according to the design requirements for the acoustic surface wave filter. For instance: 5 resonators are included in the series resonator group.

A parallel resonator group is made on the other piezoelectric substrate.

The parallel resonator group consists of several parallel resonators and electrodes.

The number of resonators included in the parallel resonator group is determined according to the design requirements for the acoustic surface wave filter. For instance: 4 resonators are included in the parallel resonator group.

The series and parallel resonator groups on the piezoelectric substrates form a trapezoidal structure.

The series and parallel resonators in trapezoidal structure can obtain better stopband suppression through the mode of multistage cascade connection.

The thicknesses of electrodes in the series resonator group and electrodes in the parallel resonator group are the same or different (optional);

The thicknesses of electrodes in the series resonator group and parallel resonator group are determined according the design requirements for the acoustic surface wave filter.

Since the relative film thickness of different materials is different, the thickness of electrodes may be the same or different, therefore, the thickness of electrodes shall be selected to realize the best performance of the acoustic surface wave filter.

The series resonator group is connected with the parallel resonator group.

The series resonator group is connected with the parallel resonator group through interconnected welding wire (optional);

Making the series resonator group on one piezoelectric substrate and scribing to get a chip, making the parallel resonator group on the other piezoelectric substrate and scribing to get another chip. Paste two chips onto their corresponding tube bases, and then connect the series resonator group with the parallel resonator group through interconnected welding wire.

The series resonator group is connected with the parallel resonator group through support plate (optional).

Making the series resonator group on one piezoelectric substrate and scribing to get a chip, making the parallel resonator group on the other piezoelectric substrate and scribing to get another chip. Prepare welded balls on electrodes of two chips, and connect the chips and the support plate by means of the flip-chip process, namely realize connection of the series resonator group with the parallel resonator group through the support plate.

The support plate is PCB (Printed Circuit Board) or ceramic plate (optional).

In conclusion, an acoustic surface wave filter provided in the implementation cases of this invention consists of two different piezoelectric substrates, a series resonator group is made on one piezoelectric substrate, a parallel resonator group is made on the other, and they form a trapezoidal structure. The series resonator group is connected with the parallel resonator group, the series resonator group is composed of several series resonators and electrodes, and the parallel resonator group is composed of several parallel resonators and electrodes; as a result, the problems that the present acoustic surface wave filters are difficult to satisfy different relative bandwidths and better rectangle coefficient simultaneously are solved; and the effects of increasing the relative bandwidth of the acoustic surface wave filter, reducing the insertion loss and optimizing the rectangle coefficient are achieved.

Two piezoelectric substrates are made of different types of materials; one piezoelectric substrate is made of lithium niobate, and the other is made of lithium tantalate or quartz (optional).

When two piezoelectric substrates are made of different types of materials, the following materials can be selected for the piezoelectric substrates: lithium tantalate and lithium niobate, or, lithium niobate and quartz.

When one piezoelectric substrate is made of lithium niobate, the tangential direction of the lithium niobate substrate is any value between 0° and 64° of rotation Y, for instance: the tangential direction of the lithium niobate substrate is 10° of rotation Y.

Two piezoelectric substrates are lithium niobate substrates in different tangential directions (optional); and the tangential direction of lithium niobate substrates is any value between 0° and 64° of rotation Y.

For instance: the tangential direction of one lithium niobate substrate is 3° of rotation Y, and the tangential direction of the other lithium niobate is 60° of rotation Y.

The specific value of the tangential direction of lithium niobate substrates is determined according to the design requirements for the acoustic surface wave filter.

When the piezoelectric substrates are made of lithium niobate, the material of electrodes may be any of copper, tungsten and gold (optional).

The material of electrodes is selected according the design requirements for the acoustic surface wave filter.

When the piezoelectric substrates are made of lithium tantalate, the material of electrodes is aluminum (optional).

The effect of eliminating parasitic mode by optimizing the thickness and period ratio of electrodes of each resonator.

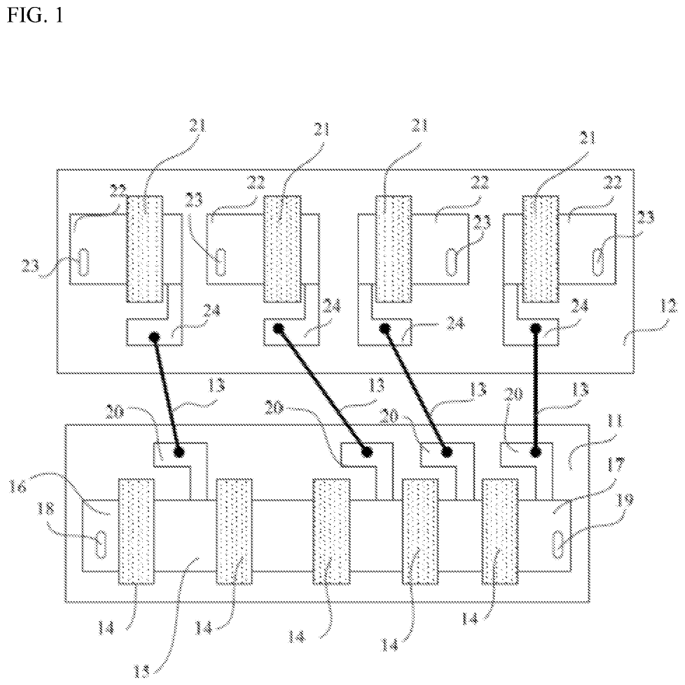

In an example of the implementation cases, as shown in FIG. 1, the series resonator group on one piezoelectric substrate 11 of the acoustic surface wave filter is connected with the parallel resonator group on the other piezoelectric substrate 12 through interconnected welding wire 13;

In this acoustic surface wave filter lithium tantalate or lithium niobate which tangential direction is any value between 0° and 64° of rotation Y is taken as the material of the piezoelectric substrate in which the series filter bank is included, and lithium niobate which tangential direction is any value between 0° and 64° of rotation Y is taken as the material of the piezoelectric substrate in which the parallel filter bank is included; when lithium niobate which tangential direction is any value between 0° and 64° of rotation Y is selected as the material of two piezoelectric substrates, the values of tangential direction of two piezoelectric substrates are different.

In FIG. 1 5 resonators 14 are made on piezoelectric substrate 11, and connected in series through electrode 15.

Electrode 16 on piezoelectric substrate 11 is the input electrode of the acoustic surface wave filter, and electrode 17 is the output electrode of the acoustic surface wave filter.

Welding wire 18 is the input lead welding wire of the acoustic surface wave filter, and welding wire 19 is the output lead welding wire of the acoustic surface wave filter.

Welding wire 18 is connected with electrodes 16 and 17.

Electrode 17 and electrode 16 are connected with electrode 15, respectively.

Electrode 20 is used to connect interconnected welding wire 13.

Electrode 20 is connected with electrodes 16 and 17.

4 resonators 21 are made on piezoelectric substrate 12 and connected in parallel.

Electrode 22 is the grounding electrode of the parallel resonator group.

Welding wire 23 is the grounding welding wire of parallel resonators, and connected with electrode 22.

Electrode 24 is used to connect interconnected welding wire 13.

Electrode 24 is connected with electrode 22.

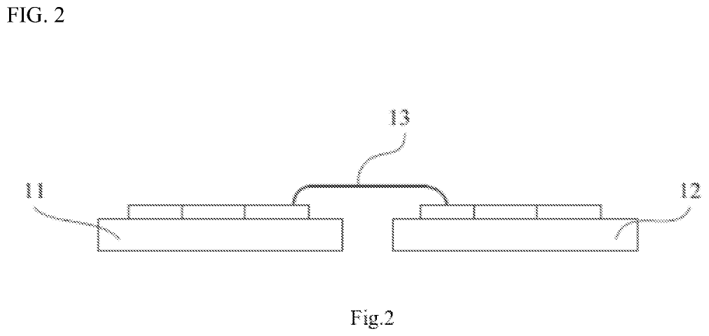

FIG. 2 shows the sectional schematic diagram of the acoustic surface wave filter as shown in FIG. 1.

It should be noted that the number of resonators in both parallel and series resonator groups can be changed according to the actual needs.

In the optional implementation cases based on the implementation case as shown in FIG. 1, the series resonator group made on piezoelectric substrate 11 and the parallel resonator group made on piezoelectric substrate 12 can also be connected through support plate.

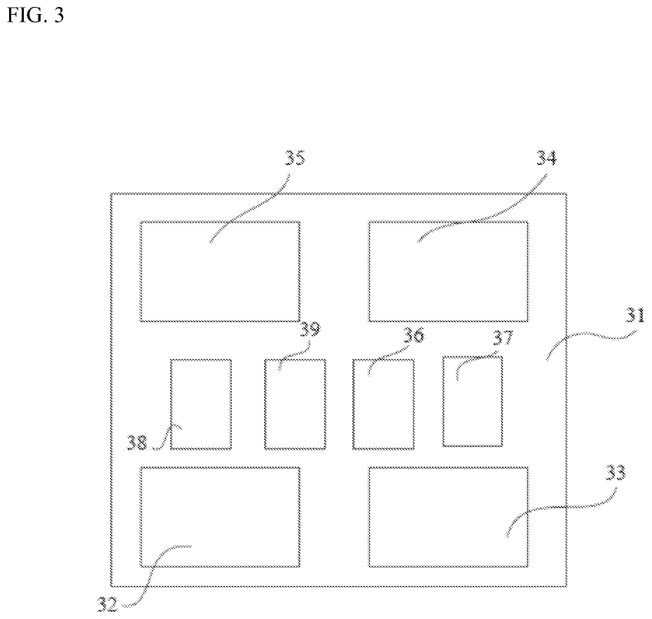

FIG. 3 shows the structural schematic diagram of a support plate as an example.

In FIG. 3 grounding electrodes 32 and 33, input electrode 34 and output electrode 35, electrodes 36, 37, 38 and 39 are included on support plate 31, and electrodes 36˜39 are interconnected metal electrodes.

In such case the series resonator group on piezoelectric substrate 11 and the parallel resonator group on piezoelectric substrate 12 are not connected through interconnected welding wire 13, namely welding wire 13 does not exist in FIG. 1.

Prepare welded balls on electrodes of the series resonator group on piezoelectric substrate 11 and the parallel resonator group on piezoelectric substrate 12, and connect two piezoelectric substrates on which the resonator groups are made with the electrodes on support plate by means of the flip-chip process to realize connection of the series resonator group with the parallel resonator group.

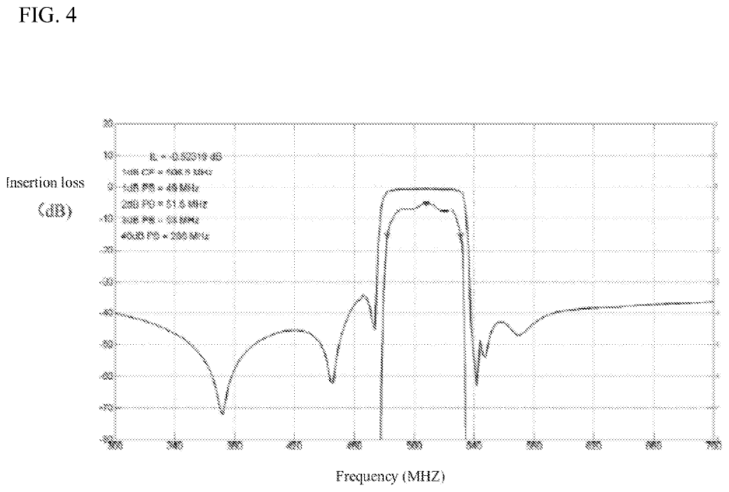

In another example of the implementation cases, the center frequency of the acoustic surface wave filter is designed at 506.5 M, the relative bandwidth of 1 dB is 9.67%, and the rectangle coefficient of 30 dB is 1.26. FIG. 4 shows the diagram of simulation result of the acoustic surface wave filter as an example.

Lithium tantalate is selected as the material of the piezoelectric substrate on which the parallel resonator group is made, and lithium niobate as the material of the piezoelectric substrate on which the series resonator group is made.

The structure of the series resonator group on one piezoelectric substrate and the parallel resonator group on the other piezoelectric substrate is similar to the structure as shown in FIG. 1, and the number of resonators in the parallel and series resonator groups is determined according to the design requirements for the acoustic surface wave filter.

Lithium tantalate is selected since its better temperature coefficient can be utilized so as to reduce the temperature coefficient of the whole acoustic surface wave filter, while the combination of lithium niobate with lithium tantalate can reduce the temperature coefficient of the acoustic surface wave filter to be 75% of the temperature coefficient of lithium niobate effectively.

In addition, quartz can also be selected as the material of the piezoelectric substrate on which the series resonator group is made, and lithium niobate as the material of the piezoelectric substrate on which the parallel resonator group is made. If quartz is combined with lithium niobate, the bandwidth of the acoustic surface wave filter will reduce accordingly, and the temperature coefficient can reach 50% of the temperature coefficient of lithium niobate so as to exhibit perfect temperature compensation.

The acoustic surface wave filter provided in the implementation cases of this invention can achieve 1%˜20% relative bandwidth; when the piezoelectric substrates made of two materials are selected, different materials interact by means of the feature that the coupling coefficients of two materials are different so as to play a role of adjusting the bandwidth.

When lithium niobate is selected as the piezoelectric material, the bigger coupling coefficient of lithium niobate material can guarantee lower insertion loss of the acoustic surface wave filter in wider range of passband.

It should be noted that the serial No. of the above-mentioned implementation cases of this invention is only for the purpose of description, but does not represents pros and cons of the implementation cases.

The foregoing only includes the better implementation cases of this invention and does not limit this invention, any modification, equivalent replacement and improvement, etc. made in the spirit and principles of this invention shall all be included in the protection scope of this invention.

What is claimed is:

1. An acoustic surface wave filter, which is characterized by including two different piezoelectric substrates, a series resonator group is made on one aforesaid piezoelectric substrate, and a parallel resonator group is made on the other aforesaid piezoelectric substrate;
The aforesaid series and parallel resonator groups on the aforesaid piezoelectric substrates form a trapezoidal structure;
The aforesaid series resonator group is connected with the aforesaid parallel resonator group;
In which, the aforesaid series resonator group is composed of several series resonators and electrodes, and the aforesaid parallel resonator group consists of several parallel resonators and electrodes.

2. As for the acoustic surface wave filter mentioned in claim 1, it is featured that the aforesaid two piezoelectric substrates are made of different types of materials;
One aforesaid piezoelectric substrate is made of lithium niobate, and the other aforesaid piezoelectric substrate is made of lithium tantalate or quartz.

3. As for the acoustic surface wave filter mentioned in claim 1, it is featured that two aforesaid piezoelectric substrates are two lithium niobate substrates in different tangential directions;
The tangential direction of the aforesaid lithium niobate is any value between 0° and 64° of rotation Y.

4. As for the acoustic surface wave filter mentioned in claim 2 or claim 3, it is featured as follows, when the aforesaid piezoelectric substrates are made of lithium niobate, the material of the aforesaid electrodes is any of copper, tungsten and gold;
When the aforesaid piezoelectric substrates are made of lithium tantalate, the material of the aforesaid electrodes is aluminum.

5. As for the acoustic surface wave filter mentioned in any of claims 1˜3, it is featured that the thicknesses of electrodes in the series resonator group and electrodes in the parallel resonator group are the same or different.

6. As for the acoustic surface wave filter mentioned in any of claims 1˜3, it is featured that the aforesaid series resonator group is connected with the aforesaid parallel resonator group through interconnected welding wire.

7. As for the acoustic surface wave filter mentioned in any of claims 1˜3, it is featured that the aforesaid series resonator group is connected with the aforesaid parallel resonator group through support plate.
